(19) United States
(12) Patent Application Publication
(10) Pub. No.: US 2025/0364217 A1
(43) Pub. Date: Nov. 27, 2025

(54) PLASMA PROCESSING APPARATUS AND MATCHING DEVICE

(71) Applicant: Tokyo Electron Limited, Tokyo (JP)

(72) Inventor: Takeshi KOBAYASHI, Iwate (JP)

(21) Appl. No.: 19/207,755

(22) Filed: May 14, 2025

(30) Foreign Application Priority Data
May 22, 2024 (JP) 2024-083612

(51) Int. Cl. H01J 37/32

(52) U.S. Cl. CPC H01J 37/32183; H01J 37/32568; H01J 37/32935

(57) ABSTRACT

A plasma processing apparatus includes: a gas supply unit; a radio-frequency power source; a pair of plasma electrodes; and a matching box. The matching box includes: a radio-frequency power supply line; a ground line; first and second load lines connected to the pair of plasma electrodes; impedance matching circuitry connected to the radio-frequency power supply line, the first load line, the second load line, and the ground line, and including a first reactance element, a radio-frequency sensor that is provided in the radio-frequency power supply line and detects the radio-frequency power; and a matching box control unit that receives a detection value from the radio-frequency sensor and control the first reactance element. The first reactance element includes: a first variable capacitor; and a second variable capacitor connected in parallel with the first variable capacitor and switching between a first state and a second state.

### CROSS-REFERENCE TO RELATED APPLICATIONS

This application is based on and claims priority from Japanese Patent Application No. 2024-083612, filed on May 22, 2024, with the Japan Patent Office, the disclosure of which is incorporated herein in its entirety by reference.

### TECHNICAL FIELD

The present disclosure relates to a plasma processing apparatus and a matching device.

### BACKGROUND

Japanese Patent Application Laid-Open Publication No. 2022-078495 discloses a plasma processing apparatus: including a chamber; a substrate support provided in the chamber and configured to support a substrate; a first electrode provided inside the substrate support; a matching box connected to the first electrode; a radio-frequency power source connected to the matching box; and a control unit. The matching box includes: lower circuitry configured by connecting a plurality of lower series circuits in parallel, each lower series circuit including a capacitor and a switching element; and upper circuitry configured by connecting a plurality of upper series circuits in parallel, each upper series circuit including a capacitor and a switching element. The control unit is configured to control the matching box by setting the switching elements of the lower series circuits or the upper series circuits to an ON state or an OFF state, thereby setting one of the lower circuitry and the upper circuitry. The control unit is also configured to control the matching box to wait until a change in impedance viewed from the matching unit toward the chamber side, the amount of change being varied by the configuration of the lower circuitry or the upper circuitry, becomes stabilized. Further, the control unit is configured to control the matching box by setting the switching elements of the lower series circuits or the upper series circuits to an ON state or an OFF state, thereby setting the other of the lower circuitry and the upper circuitry.

### SUMMARY

In view of the foregoing, according to one aspect, a plasma processing apparatus includes: a gas supply unit that supplies a processing gas; a radio-frequency power source; a pair of plasma electrodes; and a matching box disposed between the pair of plasma electrodes and the radio-frequency power source. The matching box includes: a radio-frequency power supply line configured to receive radio-frequency power from the radio-frequency power source; a ground line that is grounded; a first load line connected to one of the pair of plasma electrodes, a second load line connected to the other of the pair of plasma electrodes, impedance matching circuitry connected to the radio-frequency power supply line, the first load line, the second load line, and the ground line, and including a first reactance element; a radio-frequency sensor that is provided in the radio-frequency power supply line and detects the radio-frequency power; and a matching box control unit that receives a detection value from the radio-frequency sensor and control the first reactance element. The first reactance element includes: a first variable capacitor having a continuously variable capacitance; and a second variable capacitor connected in parallel with the first variable capacitor and configured to switch between a first state having a first capacitance and a second state having a second capacitance.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic view illustrating a configuration of a substrate processing apparatus.

FIG. 2 is a flowchart illustrating the operation of the substrate processing apparatus.

FIG. 3 is a circuit diagram illustrating circuitry that supplies radio-frequency power to the plasma electrodes.

FIG. 4 is a cross-sectional view illustrating a first variable capacitor.

FIG. 5 is a cross-sectional view illustrating a first variable capacitor.

FIG. 6 is a cross-sectional view illustrating a second variable capacitor.

FIG. 7 is a cross-sectional view illustrating a second variable capacitor.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described with reference to the accompanying drawings. In each of the drawings, the same components are denoted by the same reference numerals, and redundant descriptions may be omitted.

### [Substrate Processing Apparatus]

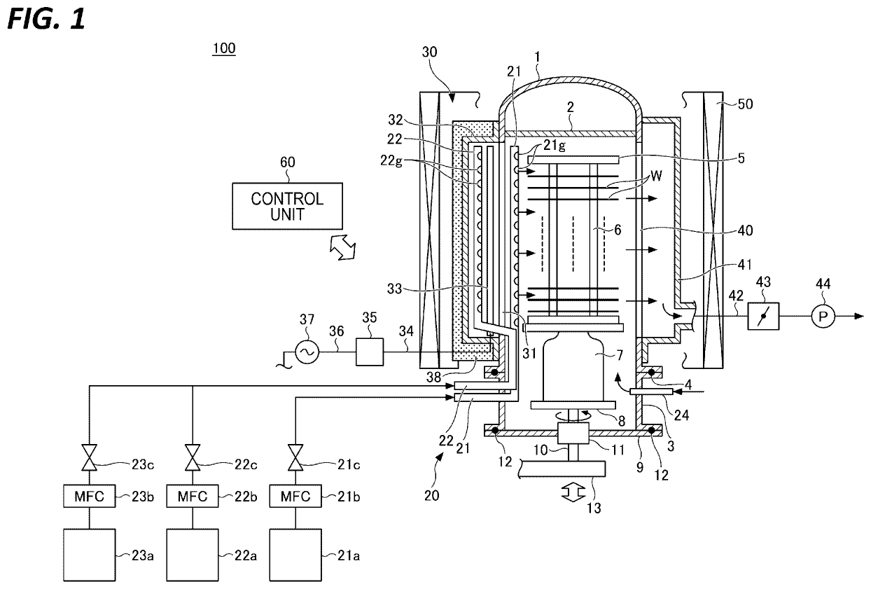

An example of a substrate processing apparatus (plasma processing apparatus) 100 according to the present embodiment will be described with reference to FIG. 1. FIG. 1 is a schematic view illustrating a configuration of the substrate processing apparatus 100. In the following description, the substrate processing apparatus 100 is described as an example of a film deposition apparatus configured to form a silicon nitride film on a substrate W by an atomic layer deposition (ALD) process using a plasma of a silicon-containing gas and a nitrogen-containing gas.

The substrate processing apparatus 100 includes a processing container 1 having a cylindrical shape with a ceiling and an open lower end. The entire processing container 1 is made of, for example, quartz. A ceiling plate 2 made of quartz is provided near the upper end inside the processing container 1, and a region below the ceiling plate 2 is sealed. A cylindrical metal manifold 3 is connected to the opening at the lower end of the processing container 1 via a sealing member 4 such as an O-ring.

The manifold 3 supports the lower end of the processing container 1, and from below the manifold 3, a wafer boat 5 (substrate holder), on which a large number (e.g., 25 to 150) of semiconductor wafers (hereinafter, referred to as “substrates W”) are mounted in multiple stages, is inserted into the processing container 1. In this manner, a plurality of substrates W are substantially horizontally accommodated inside the processing container 1 at intervals along the vertical direction. The wafer boat 5 is made of, for example, quartz. The wafer boat 5 includes three rods 6 (two of which are illustrated in FIG. 1), and the substrates W are supported by grooves (not illustrated) formed in the rods 6.

The wafer boat 5 is placed on a table 8 via a heat-insulating cylinder 7 made of quartz. The table 8 is supported on a rotary shaft 10 that penetrates a metal (stainless) lid 9 configured to open/close an opening at the lower end of the manifold 3.

A magnetic fluid seal 11 is provided at the penetration portion of the rotary shaft 10 to hermetically seal the rotary shaft 10 while allowing it to rotate. A sealing member 12 is provided between the peripheral portion of the lid 9 and the lower end of the manifold 3 to maintain the airtightness of the interior of the processing container 1.

The rotary shaft 10 is attached to a distal end of an arm 13 supported by an elevating mechanism (not illustrated), such as a boat elevator, and the wafer boat 5 and the lid 9 move up and down integrally, and are inserted into and removed from the processing container 1. The table 8 may be fixed to the lid 9 such that processing of the substrates W is performed without rotating the wafer boat 5.

The substrate processing apparatus 100 includes a gas supply unit 20 (a processing gas supply unit) configured to supply a predetermined gas, such as a processing gas or purge gas, into the processing container 1.

The gas supply unit 20 includes gas supply pipes 21, 22, and 24. The gas supply pipe 21 is made of, for example, quartz, penetrates the side wall of the manifold 3 inwardly, and then bends upward to extend vertically. A vertical portion of the gas supply pipe 21 includes a plurality of gas holes 21g formed at predetermined intervals over a length corresponding to the wafer holding range of the wafer boat 5 in the vertical direction. Each gas hole 21g ejects gas in a horizontal direction. The gas supply pipe 22 is made of, for example, quartz, penetrates the side wall of the manifold 3 inwardly, and then bends upward to extend vertically. A vertical portion of the gas supply pipe 22 includes a plurality of gas holes 22g formed at predetermined intervals over a length corresponding to the wafer holding range of the wafer boat 5 in the vertical direction. Each gas hole 22g ejects gas in a horizontal direction. The gas supply pipe 24 is made of, for example, quartz, and includes a short quartz tube provided to penetrate the side wall of the manifold 3.

The vertical portion of the gas supply pipe 21 (where the gas holes 21g are formed) is disposed inside the processing container 1. A processing gas (source gas) is supplied to the gas supply pipe 21 from a gas source 21a via a gas line. The gas line is provided with a flow controller 21b and an opening/closing valve 21c. Accordingly, the processing gas from the gas source 21a is supplied into the processing container 1 via the gas line and the gas supply pipe 21. The processing gas (source gas) supplied from the gas source 21a is, for example, a precursor gas that adsorbs onto the substrates W, such as a silicon-containing gas. The silicon-containing gas is, for example, dichlorosilane (DCS (SiH₂Cl₂)).

The vertical portion of the gas supply pipe 22 (where the gas holes 22g are formed) is disposed in a plasma generation space described later. A processing gas (first processing gas) is supplied to the gas supply pipe 22 from a gas source 22a via a gas line. The gas line is provided with a flow controller 22b and an opening/closing valve 22c. Accordingly, the processing gas from the gas source 22a is supplied into the plasma generation space via the gas line and the gas supply pipe 22, where the processing gas is converted into a plasma and then supplied into the processing container 1. The processing gas (first processing gas) supplied from the gas source 22a is, for example, a reaction gas that reacts with a precursor gas adsorbed on the substrate W to form a film (e.g., a silicon nitride film), and is, for example, a nitrogen-containing gas. The nitrogen-containing gas is, for example, NH₃.

A processing gas (second processing gas) is also supplied to the gas supply pipe 22 from a gas source 23a via a gas line. The gas line is provided with a flow controller 23b and an opening/closing valve 23c. The processing gas (second processing gas) supplied from the gas source 23a is a gas different from the processing gas (first processing gas) supplied from the gas source 22a. Accordingly, the processing gas from the gas source 23a is supplied into the plasma generation space via the gas line and the gas supply pipe 22, where the processing gas is converted into a plasma and then supplied into the processing container 1. The processing gas (second processing gas) supplied from the gas source 23a is, for example, a modification gas that modifies the formed film. The modification gas is, for example, hydrogen (H₂).

The processing gas (source gas) supplied from the gas source 21a, the processing gas (first processing gas (reaction gas)) supplied from the gas source 22a, and the processing gas (second processing gas (modification gas)) supplied from the gas source 23a are not limited thereto.

A purge gas is supplied to the gas supply pipe 24 from a purge gas source (not illustrated) via a gas line. The gas line (not illustrated) is provided with a flow controller (not illustrated) and an opening/closing valve (not illustrated). Accordingly, the purge gas from the purge gas source is supplied into the processing container 1 via the gas line and the gas supply pipe 24. The purge gas supplied from the purge gas source is, for example, an inert gas such as argon (Ar) or nitrogen (N₂). Although the purge gas has been described as being supplied into the processing container 1 via the gas supply pipe 24, the purge gas is not limited thereto and may be supplied into the processing container 1 via any of the gas supply pipes 21 and 22.

A plasma generation mechanism 30 is provided at a portion of the side wall of the processing container 1. The plasma generation mechanism 30 converts the processing gases (first and second processing gases) from the gas sources 22a and 23a into a plasma.

The plasma generation mechanism 30 includes: a plasma partition wall 32; a pair of plasma electrodes 33 (only one of which is illustrated in FIG. 1); a power supply line 34; a matching box 35; a coaxial cable 36; a radio-frequency power source 37; and an insulating protective cover 38.

The plasma partition wall 32 is hermetically welded to the outer wall of the processing container 1. The plasma partition wall 32 is made of, for example, quartz. The plasma partition wall 32 has a concave cross-sectional shape and covers an opening 31 formed in the side wall of the processing container 1. The opening 31 is elongated in the vertical direction so as to cover all of the substrates W supported by the wafer boat 5 in the vertical direction. A gas supply pipe 22 configured to eject a processing gas is disposed in a plasma generation space defined by the plasma partition wall 32 and communicating with the interior of the processing container 1. The gas supply pipe 21 configured to eject a processing gas is provided outside the plasma generation space, at a position close to the substrates W along the inner wall of the processing container 1.

A pair of plasma electrodes 33 (only one of which is illustrated in FIG. 1) each have an elongated shape and are disposed to face each other along the vertical direction on the outer surfaces of the opposing side walls of the plasma partition wall 32. Each plasma electrode 33 is held, for example, by a holding unit (not illustrated) provided on the side surface of the plasma partition wall 32. A power supply line 34 is connected to the lower end of each plasma electrode 33.

The power supply line 34 electrically connects each plasma electrode 33 to the matching box 35. In the illustrated example, one end of the power supply line 34 is connected to the lower end of each plasma electrode 33, and the other end is connected to the matching box 35.

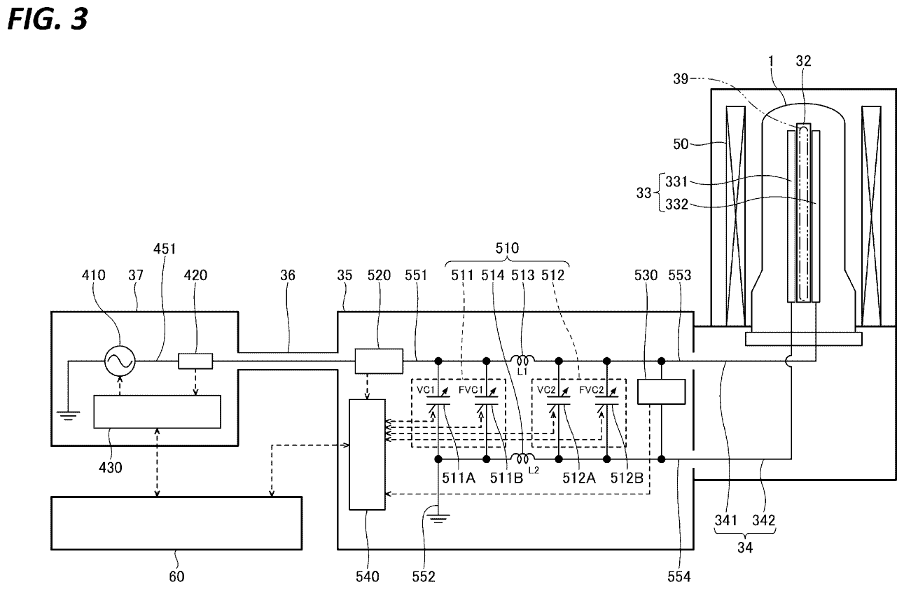

The matching box 35 includes impedance matching circuitry 510 (see, e.g., FIG. 3 described later) and performs impedance matching between the radio-frequency power source 37 and the substrate processing apparatus 100 (the pair of plasma electrodes 33).

The coaxial cable 36 electrically connects the matching box 35 to the radio-frequency power source 37.

The radio-frequency power source 37 is connected to the lower ends of the plasma electrodes 33 via the coaxial cable 36, the matching box 35, and the power supply line 34, and supplies radio-frequency power, for example, 13.56 MHz, to the pair of plasma electrodes 33. As a result, radio-frequency power is supplied into the plasma generation space defined by the plasma partition wall 32. The processing gas (a first processing gas or a second processing gas) ejected from the gas supply pipe 22 is converted into a plasma in the plasma generation space where the radio-frequency power is supplied, and then introduced into the interior of the processing container 1 through the opening 31.

The insulating protective cover 38 is provided outside the plasma partition wall 32 so as to cover the plasma partition wall 32. A coolant passage (not illustrated) is provided in an inner portion of the insulating protective cover 38, and the plasma electrodes 33 are cooled by flowing a coolant such as cooled nitrogen (N₂) gas through the coolant passage. In addition, a shield (not illustrated) may be provided between the plasma electrodes 33 and the insulating protective cover 38 so as to cover the plasma electrodes 33. The shield is made of, for example, a good conductor such as a metal and is grounded.

An exhaust port 40 (an exhaust section) configured to evacuate the interior of the processing container 1 is provided at a portion of the side wall of the processing container 1 that faces the opening 31. The exhaust port 40 is vertically elongated to correspond to the wafer boat 5. A U-shaped cross-sectional exhaust port cover member 41 is attached to a portion corresponding to the exhaust port 40 to cover the exhaust port 40. The exhaust port cover member 41 extends upwards along the side wall of the processing container 1. An exhaust pipe 42 is connected to a lower portion of the exhaust port cover member 41 to evacuate the processing container 1 through the exhaust port 40. A pressure control valve 43 configured to control the pressure inside the processing container 1 and an exhaust device 44 including a vacuum pump are connected to the exhaust pipe 42, and the interior of the processing container 1 is evacuated by the exhaust device 44 through the exhaust pipe 42.

A cylindrical heating mechanism 50 is provided around the processing container 1. The heating mechanism 50 heats the processing container 1 and the substrates W therein. The heating mechanism 50 controls the temperature of the processing container 1 to a desired temperature. Accordingly, the substrates W inside the processing container 1 are heated by, for example, radiant heat from the wall of the processing container 1.

The substrate processing apparatus 100 also includes a control unit 60. The control unit 60 controls the operation of each component of the substrate processing apparatus 100. For example, the control unit 60 controls the supply and stop of each gas by opening/closing the opening/closing valves 21c and 22c, controls the gas flow rates via the flow controllers 21b and 22b, and controls exhaust via the exhaust device 44.

The control unit 60 also performs ON/OFF control of the radio-frequency power supplied by the radio-frequency power source 37 and controls the temperature of the processing container 1 and the substrates W therein via the heating mechanism 50. Furthermore, the control unit 60 controls the matching box 35.

The control unit 60 may be, for example, a computer. A program for operating each component of the substrate processing apparatus 100 is stored on a storage medium. The storage medium may be, for example, a flexible disk, a compact disk, a hard disk, a flash memory, or a DVD.

In the substrate processing apparatus 100 illustrated in FIG. 1, an example has been described in which the plasma of the processing gas is generated by the plasma generation mechanism 30 provided on the side of the processing container 1, and the activated processing gas is supplied to the substrates W inside the processing container 1. However, the present disclosure is not limited thereto. The substrate processing apparatus 100 may alternatively be configured to generate a plasma of the processing gas inside the processing container 1 and to supply the activated processing gas to the substrates W therein. In such a case, the pair of plasma electrodes 33 may be disposed to face each other with the processing container 1 interposed therebetween. In addition, the wall of the processing container 1 may serve as a plasma partition wall that partitions the plasma generation space.

### [Substrate Processing Process in Substrate Processing Apparatus]

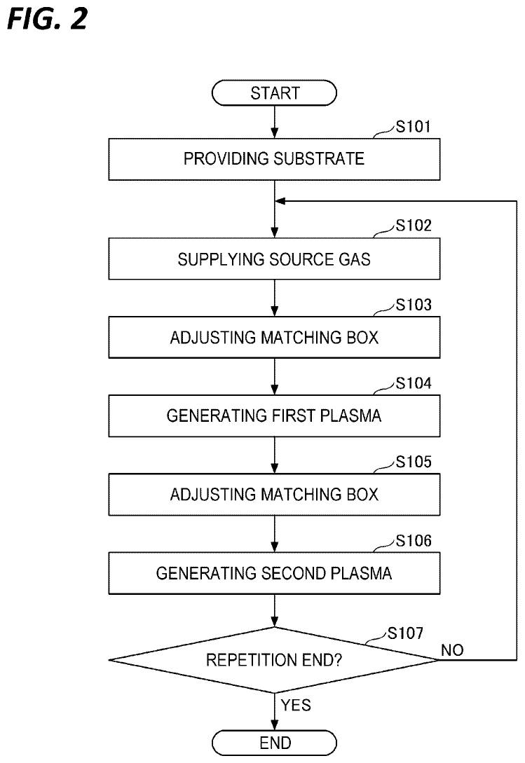

Next, an example of the operation of the substrate processing apparatus 100 will be described with reference to FIG. 2. FIG. 2 is a flowchart illustrating the operation of the substrate processing apparatus 100.

In step S101, substrates W are provided. Here, the wafer boat 5 on which the substrates W are placed is inserted into the processing container 1.

In step S102, a source gas is supplied. Here, the control unit 60 controls the flow controller 21b and the opening/closing valve 21c to supply the source gas from the gas source 21a into the processing container 1. As a result, for example, a silicon-containing gas is adsorbed onto the surfaces of the substrates W.

In step S103, the matching box 35 is adjusted. Here, the capacitance of the variable capacitors (variable capacitors 511A, 511B, 512A, and 512B, which will be described later with reference to FIG. 3) of the matching box 35 is preset to a capacitance suitable for ignition of the plasma in step S104 described later.

In step S104, a first plasma is generated. Here, the control unit 60 controls the flow controller 22b and the opening/closing valve 22c to supply a first processing gas from the gas source 22a into the plasma generation space. The control unit 60 also controls the radio-frequency power source 37 to supply radio-frequency power to the plasma electrodes 33. As a result, the first processing gas ejected from the gas supply pipe 22 is converted into a plasma in the plasma generation space where the radio-frequency power is supplied, and then supplied into the interior of the processing container 1 through the opening 31. In addition, a matching box control unit 540 (see, e.g., FIG. 3 described later) of the matching box 35 finely adjusts the variable capacitors (variable capacitors 511A and 512A described later with reference to FIG. 3) such that the power of the reflected wave detected by a radio-frequency sensor 520 (see, e.g., FIG. 3 described later) approaches zero. This allows, for example, the silicon-containing gas adsorbed on the surfaces of the substrates W to be nitrided, thereby forming a silicon nitride film on the surface of each substrate W.

In step S105, the matching box 35 is adjusted. Here, the capacitance of the variable capacitors (variable capacitors 511A, 511B, 512A, and 512B, which will be described later with reference to FIG. 3) of the matching box 35 is preset to a capacitance suitable for ignition of the plasma in step S106 described later.

In step S106, a second plasma is generated. Here, the control unit 60 controls the flow controller 23b and the opening/closing valve 23c to supply a second processing gas from the gas source 23a into the plasma generation space. The control unit 60 also controls the radio-frequency power source 37 to supply radio-frequency power to the plasma electrodes 33. As a result, the second processing gas ejected from the gas supply pipe 22 is converted into a plasma in the plasma generation space where the radio-frequency power is supplied, and then supplied into the interior of the processing container 1 through the opening 31. In addition, a matching box control unit 540 (see, e.g., FIG. 3 described later) of the matching box 35 finely adjusts the variable capacitors (variable capacitors 511A and 512A described later with reference to FIG. 3) such that the power of the reflected wave detected by a radio-frequency sensor 520 (see, e.g., FIG. 3 described later) approaches zero. This allows, for example, the silicon nitride film formed on the surface of the substrate W to be modified by the plasma of the second processing gas.

In step S107, it is determined whether to terminate the repeated processing. When the repeated processing is not to be terminated (S107: NO), the processing by the control unit 60 returns to step S102, and the processing from step S102 to step S106 is repeated. When the repeated processing is to be terminated (S107: YES), the processing by the control unit 60 is terminated.

As described above, in the substrate processing illustrated in FIG. 2, one cycle includes: a step of supplying a source gas (S102); steps of generating a plasma of a first processing gas (first plasma) and performing processing on the substrates W (S103 and S104); and steps of generating a plasma of a second processing gas (second plasma) and performing processing on the substrates W (S105 and S106). By repeating this cycle a predetermined number of times, a silicon nitride film having a desired film thickness is formed on the substrates W.

The substrate processing is not limited to the example illustrated in FIG. 2. The substrate processing may include at least a step of generating a plasma of a first processing gas (first plasma) and performing processing on the substrates W, and a step of generating a plasma of a second processing gas (second plasma) different from the first processing gas and performing processing on the substrates W. These steps may be defined as one cycle, and the cycle may be repeated.

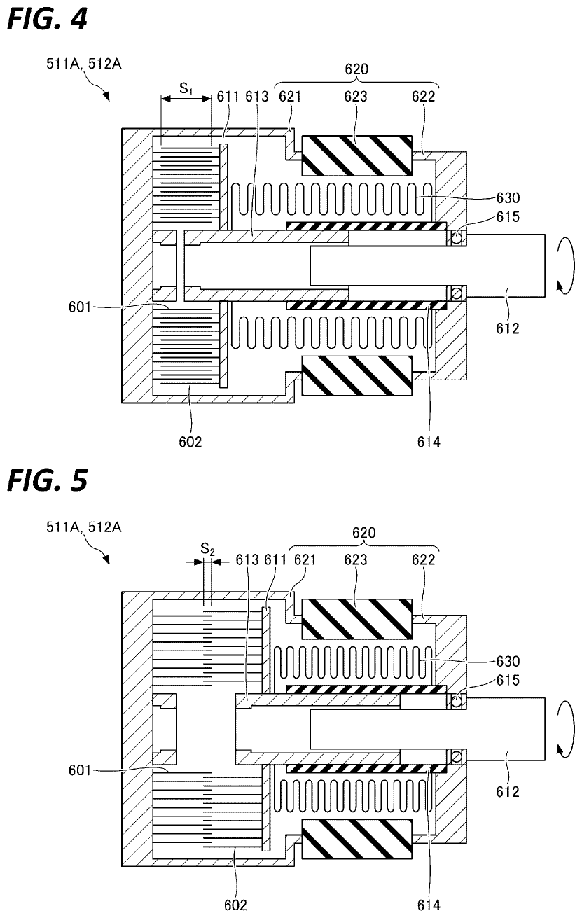

Here, the capacitance of the variable capacitors of the matching box 35 for bringing the power of a reflected wave close to zero when generating a plasma of the first processing gas (first plasma) is significantly different from the capacitance of the variable capacitors of the matching box 35 for bringing the power of a reflected wave close to zero when generating a plasma of the second processing gas (second plasma). Accordingly, a time (i.e., the time in steps S103 and S105) is required to adjust the matching box 35 before switching the plasma to be generated. In addition, an increase in the operating range or number of operations of the variable capacitors may affect the service life of bellows (the bellows 630 illustrated in FIGS. 4 and 5, which will be described later) provided in the variable capacitors, which may shorten the periodic replacement cycle of the matching box 35.

### [Matching Box]

Next, the matching box 35 will be further described with reference to FIG. 3. FIG. 3 is a circuit diagram illustrating circuitry that supplies radio-frequency power to the plasma electrodes 33. In FIG. 3, signal flows are illustrated with dashed arrows.

The plasma electrodes 33 include one plasma electrode 331 and the other plasma electrode 332. The pair of plasma electrodes 331 and 332 are disposed to face each other outside the plasma partition wall 32. A plasma generation space is formed to generate plasma 39 inside the plasma partition wall 32.

The radio-frequency power source 37 includes a power source 410, a radio-frequency sensor 420, and a power source control unit 430. The radio-frequency power source 37 also includes a radio-frequency line 451.

Radio-frequency power is output from the power source 410 through the radio-frequency line 451.

The power source 410 includes, for example, a radio-frequency oscillator and an amplifier. The radio-frequency oscillator is an oscillator configured to generate a sine wave or fundamental wave of a predetermined frequency (e.g., 13.56 MHz). The amplifier is an amplifier configured to amplify the sine wave or fundamental wave output from the radio-frequency oscillator with a variable gain or amplification factor. The power source 410 is controlled by the power source control unit 430.

A radio frequency (RF) sensor 420 is provided on the radio-frequency line 451 and detects radio-frequency power output from the radio-frequency power source 37. The radio-frequency sensor 420 includes a directional coupler on the radio-frequency line 451. The radio-frequency sensor 420 detects the power PF1 of a forward wave that propagates forward on the radio-frequency line 451, i.e., from the radio-frequency power source 37 toward the matching box 35. The radio-frequency sensor 420 also detects the power RF1 of a reflected wave that propagates in the reverse direction on the radio-frequency line 451, i.e., from the matching box 35 toward the radio-frequency power source 37. The radio-frequency sensor 420 outputs a detection result to the power source control unit 430.

The power source control unit 430 controls the power source 410 in accordance with a control signal from the control unit 60. The power source control unit 430 also controls the power source 410 based on the detection result detected by the radio-frequency sensor 420. In addition, the power source control unit 430 outputs the detection result detected by the radio-frequency sensor 420 to the control unit 60.

The coaxial cable 36 connects the radio-frequency power source 37 to the matching box 35. Specifically, an inner conductor (core wire) of the coaxial cable 36 connects the radio-frequency line 451 of the radio-frequency power source 37 and the radio-frequency power supply line 551 of the matching box 35. An outer conductor (shield) of the coaxial cable 36 is grounded.

The matching box 35 includes impedance matching circuitry 510, a radio-frequency sensor 520, a voltage sensor 530, and a matching box control unit 540. The matching box 35 also includes a radio-frequency power supply line 551, a ground line 552, a first load line 553, and a second load line 554.

The radio-frequency power supply line 551 is connected to the radio-frequency line 451 of the radio-frequency power source 37 via the coaxial cable 36. That is, the radio-frequency power supply line 551 is a line to which radio-frequency power is supplied from the radio-frequency power source 37.

The ground line 552 is a line that is grounded.

The first load line 553 is connected to one plasma electrode 331 via a power supply line 341. The second load line 554 is connected to the other plasma electrode 332 via a power supply line 342.

The impedance matching circuitry 510 includes a plurality of reactance elements 511 to 514. The impedance matching circuitry 510 is connected to the radio-frequency power supply line 551, the ground line 552, the first load line 553, and the second load line 554.

A first reactance element 511 is disposed between the radio-frequency power supply line 551 and the ground line 552. The first reactance element 511 is a variable capacitor having an adjustable capacitance. The first reactance element 511 includes a first variable capacitor 511A and a second variable capacitor 511B. The first variable capacitor 511A and the second variable capacitor 511B are connected in parallel. That is, the capacitance of the first reactance element 511 is the sum (VC1+FVC1) of the capacitance VC1 of the first variable capacitor 511A and the capacitance FVC1 of the second variable capacitor 511B. The first variable capacitor 511A and the second variable capacitor 511B are controlled by the matching box control unit 540.

The first variable capacitor 511A is a capacitor having a continuously (steplessly) variable capacitances. The first variable capacitor 511A will be described later with reference to FIGS. 4 and 5.

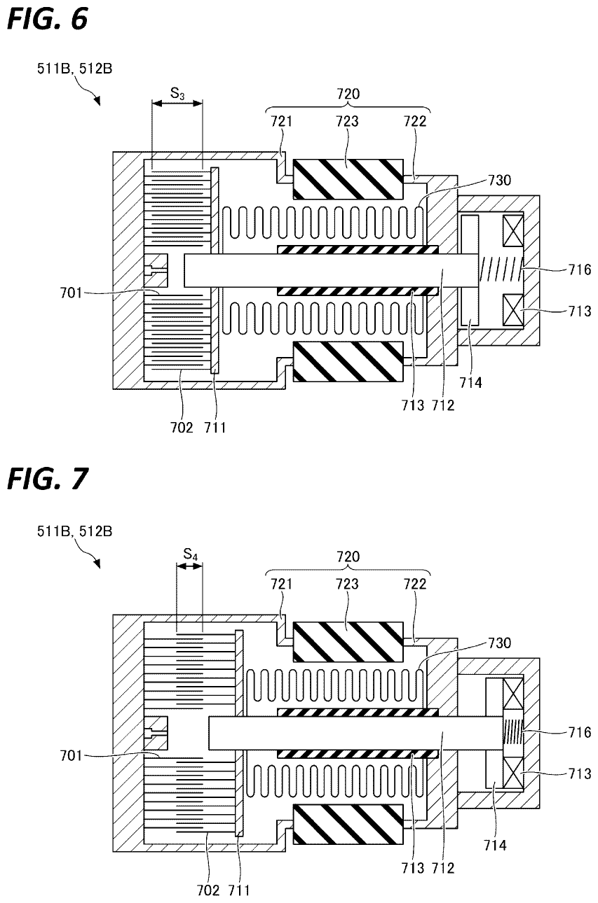

The second variable capacitor 511B is a capacitor configured to be switchable between a first state having a first capacitance and a second state having a second capacitance. The second variable capacitor 511B will be described later with reference to FIGS. 6 and 7.

A second reactance element 512 is disposed between the first load line 553 and the second load line 554. The second reactance element 512 is a variable capacitor having an adjustable capacitance. The second reactance element 512 includes a third variable capacitor 512A and a fourth variable capacitor 512B. The third variable capacitor 512A and the fourth variable capacitor 512B are connected in parallel. That is, the capacitance of the second reactance element 512 is the sum (VC2+FVC2) of the capacitance VC2 of the third variable capacitor 512A and the capacitance FVC2 of the fourth variable capacitor 512B. The third variable capacitor 512A and the fourth variable capacitor 512B are controlled by the matching box control unit 540.

The third variable capacitor 512A is a capacitor having a continuously (steplessly) variable capacitance. The third variable capacitor 512A will be described later with reference to FIGS. 4 and 5.

The fourth variable capacitor 512B is a capacitor configured to be switchable between a third state having a third capacitance and a fourth state having a fourth capacitance. The fourth variable capacitor 512B will be described later with reference to FIGS. 6 and 7.

A third reactance element 513 is disposed between the radio-frequency power supply line 551 and the first load line 553. The third reactance element 513 is an inductor (coil) having an inductance L1.

A fourth reactance element 514 is disposed between the ground line 552 and the second load line 554. The fourth reactance element 514 is an inductor (coil) having an inductance L2.

The reactance elements 511 to 514 may optionally include at least one of a fixed capacitor (e.g., parasitic capacitance), a fixed inductor (e.g., parasitic inductance), and a fixed resistor (e.g., parasitic resistance).

The radio-frequency (radio frequency (RF)) sensor 520 is provided on the radio-frequency power supply line 551 and detects radio-frequency power supplied from the radio-frequency power source 37. The radio-frequency sensor 520 includes a directional coupler on the radio-frequency power supply line 551. The radio-frequency sensor 520 detects the power PF2 of a forward wave that propagates forward on the radio-frequency power supply line 551, i.e., from the radio-frequency power source 37 toward the matching box 35. The radio-frequency sensor 520 also detects the power RF2 of a reflected wave that propagates in the reverse direction on the radio-frequency power supply line 551, i.e., from the matching box 35 toward the radio-frequency power source 37. The radio-frequency sensor 520 outputs a detection result to the matching box control unit 540.

The voltage sensor 530 detects a potential difference between the first load line 553 and the second load line 554, and detects a peak-to-peak value of the potential difference. The voltage sensor 530 outputs the detection result to the matching box control unit 540.

The matching box control unit 540 controls the first reactance element 511 and the second reactance element 512 of the impedance matching circuitry 510 in accordance with a control signal from the control unit 60. The matching box control unit 540 also controls the first reactance element 511 and the second reactance element 512 of the impedance matching circuitry 510 based on detection results obtained by the radio-frequency sensor 520 and the voltage sensor 530. In addition, the matching box control unit 540 outputs the detection results obtained by the radio-frequency sensor 520 and the voltage sensor 530 to the control unit 60.

The power supply line 34 includes a power supply line 341 and a power supply line 342. The power supply line 341 connects the first load line 553 of the matching box 35 to one plasma electrode 331. The power supply line 342 connects the second load line 554 of the matching box 35 to the other plasma electrode 332.

With this configuration, the matching box 35 is configured to allow the matching box control unit 540 to control the capacitance of the first reactance element 511 and the second reactance element 512.

Accordingly, the matching box control unit 540 controls the capacitance of the first reactance element 511 and the second reactance element 512 such that the power RF2 of the reflected wave is reduced (approaches zero), based on the detection result of the radio-frequency sensor 520. In other words, the matching box control unit 540 controls the capacitance of the first reactance element 511 and the second reactance element 512 so that the impedance on the load side including the impedance matching circuitry 510 becomes a predetermined impedance.

In addition, the matching box control unit 540 controls the capacitance of the first reactance element 511 and the second reactance element 512 such that the peak-to-peak value of the voltage between the plasma electrodes 331 and 332 becomes a predetermined set value, based on the detection result of the voltage sensor 530.

As described above, the matching box 35 illustrated in FIG. 3 is capable of performing impedance matching and adjusting the peak-to-peak value of the voltage between the plasma electrodes 331 and 332.

### [First Variable Capacitor 511A and Third Variable Capacitor 512A]

Next, the first variable capacitor 511A that constitutes the first reactance element 511 will be described with reference to FIGS. 4 and 5. FIGS. 4 and 5 are cross-sectional views of the first variable capacitor 511A.

The third variable capacitor 512A that constitutes the second reactance element 512 has the same structure as the first variable capacitor 511A, and a redundant description is omitted. The range of variable capacitance may differ between the first variable capacitor 511A and the third variable capacitor 512A.

The first variable capacitor 511A includes an electrode 601, an electrode 602, a support 611, a rotary shaft 612, a nut 613, a sleeve 614, a bearing 615, a housing 620, and a bellows 630.

The housing 620 includes a first housing 621, a second housing 622, and an insulator 623. The insulator 623 is provided between the first housing 621 and the second housing 622 and insulates the first housing 621 from the second housing 622.

The electrode 601 serves as one of the electrodes that constitutes the capacitor. The electrode 601 includes a plurality of cylindrical conductors and is supported by the first housing 621 of the housing 620.

The electrode 602 serves as the other electrode that constitutes the capacitor. The electrode 602 includes a plurality of cylindrical conductors and is supported by the support 611. The diameters of cylindrical conductors of the electrodes 601 and 602 are different, and each of the conductors of the electrode 602 has a diameter that allows insertion between corresponding adjacent conductors of the electrode 601.

By inserting each conductor of the electrode 602 between corresponding adjacent conductors of electrodes 601, the opposing surface area between the electrode 601 and the electrode 602 changes. In the example of FIG. 4, the opposing surface area between the electrodes 601 and 602 is an area S1. In the example of FIG. 5, the opposing surface area is an area S2.

The rotary shaft 612 is rotatably supported by the second housing 622 of the housing 620 via the bearing 615. The sleeve 614 is fixed to the second housing 622. The sleeve 614 prevents the nut 613 from rotating about the rotation axis of the rotary shaft 612 and guides the nut 613 to move along the axial direction of the rotary shaft 612. The support 611 is fixed to the nut 613.

The rotary shaft 612 and the nut 613 constitute a rotation-to-linear motion conversion mechanism that converts the rotational motion of the rotary shaft 612 into the linear motion of the nut 613. A driving motor (not illustrated) configured to rotate the rotary shaft 612 and a rotation sensor (not illustrated) (e.g., a potentiometer or an encoder) configured to detect the rotation of the rotary shaft 612 are connected to the rotary shaft 612. The matching box control unit 540 controls the capacitance by controlling the driving motor based on the detection value from the rotation sensor.

By rotating the rotary shaft 612 in one direction, the nut 613 moves in an extending direction (to the left in FIGS. 4 and 5) along the axis of the rotary shaft 612. That is, the support 611 moves in a direction approaching the electrode 601. In other words, the support 611 moves in a direction in which each conductor of the electrode 602 is inserted between corresponding adjacent conductors of the electrode 601. As a result, the opposing surface area between the electrode 601 and the electrode 602 increases, and the capacitance increases.

By rotating the rotary shaft 612 in the other direction opposite to the one direction, the nut 613 moves in a contracting direction (to the right in FIGS. 4 and 5) along the axis of the rotary shaft 612. That is, the support 611 moves in a direction away from the electrode 601. In other words, the support 611 moves in a direction in which each conductor of the electrode 602 is withdrawn from between corresponding adjacent electrodes 601. As a result, the opposing surface area between the electrode 601 and the electrode 602 decreases, and the capacitance decreases.

### [Second Variable Capacitor 511B and Fourth Variable Capacitor 512B]

Next, the second variable capacitor 511B, which constitutes the first reactance element 511, will be described with reference to FIGS. 6 and 7. FIGS. 6 and 7 are cross-sectional views of the second variable capacitor 511B.

The fourth variable capacitor 512B, which constitutes the second reactance element 512, has the same structure as the second variable capacitor 511B, and a redundant description is omitted. The range of variable capacitance may differ between the second variable capacitor 511B and the fourth variable capacitor 512B.

The second variable capacitor 511B includes an electrode 701, an electrode 702, a support 711, a drive shaft 712, a sleeve 713, a magnetic member 714, an electromagnet 715, an elastic element 716, a housing 720, and a bellows 730.

The housing 720 includes a first housing 721, a second housing 722, and an insulator 723. The insulator 723 is provided between the first housing 721 and the second housing 722 and insulates the first housing 721 from the second housing 722.

The electrode 701 serves as one of the electrodes that constitute the capacitor. The electrode 701 includes a plurality of cylindrical conductors and is supported by the first housing 721 of the housing 720.

The electrode 702 serves as the other of the electrodes that constitute the capacitor. The electrode 702 includes a plurality of cylindrical conductors and is supported by the support 711. The diameters of the cylindrical conductors of the cylindrical electrodes 701 and 702 are different, and each conductor of the electrode 702 has a diameter that allows insertion between corresponding adjacent conductors of the electrode 701.

By inserting each conductor of the electrode 702 between corresponding adjacent conductors of electrodes 701, the opposing surface area between the electrode 701 and the electrode 702 changes. In the example of FIG. 6, the opposing surface area between the electrodes 701 and 702 is an area S3. In the example of FIG. 7, the opposing surface area between the electrodes 701 and 702 is an area S4.

The sleeve 713 is fixed to a second housing 722. The sleeve 713 prevents the drive shaft 712 from rotating about its axis and guides the drive shaft 712 to move in the axial direction. The support 711 is fixed to the drive shaft 712. The magnetic member 714 is also fixed to the drive shaft 712. The elastic element 716 biases the magnetic member 714 in a direction away from the electromagnet 715. The matching box control unit 540 controls the ON/OFF of power supply to the electromagnet 715.

In a state where no power is supplied to the electromagnet 715 (first state), as illustrated in FIG. 6, the magnetic member 714 is biased in a direction away from the electromagnet 715 by the elastic element 716. As a result, the opposing surface area between the electrode 701 and the electrode 702 becomes area S3, and the capacitance increases.

In a state where power is supplied to the electromagnet 715 (second state), as illustrated in FIG. 7, the magnetic member 714 is attracted to the electromagnet 715 against the biasing force of the elastic element 716. As a result, the opposing surface area between the electrode 701 and the electrode 702 becomes area S4, and the capacitance decreases.

With this configuration, in step S103 for forming the first plasma, the second variable capacitor 511B is set to the first state (one of the states illustrated in FIG. 6 or FIG. 7), and the fourth variable capacitor 512B is set to the third state (one of the states illustrated in FIG. 6 or FIG. 7). Then, in step S104, the matching box control unit 540 finely adjusts the first variable capacitor 511A and the third variable capacitor 512A such that the power of the reflected wave detected by the radio-frequency sensor 520 approaches zero.

In step S105 for forming the second plasma, the second variable capacitor 511B is set to the second state (the other of the state different from the first state illustrated in FIG. 6 or FIG. 7), and the fourth variable capacitor 512B is set to the fourth state (the other state different from the third state illustrated in FIG. 6 or FIG. 7). Then, in step S106, the matching box control unit 540 finely adjusts the first variable capacitor 511A and the third variable capacitor 512A such that the power of the reflected wave detected by the radio-frequency sensor 520 approaches zero.

Here, when the first reactance element 511 is configured with only the first variable capacitor 511A, the capacitance is significantly changed when switching the plasma, and a switching time is required. In addition, the operating range of the bellows 630 would become longer, which may adversely affect the fatigue life of the bellows 630 and shorten the periodic replacement cycle of the matching box 35.

In contrast, when the first reactance element 511 is configured with the first variable capacitor 511A and the second variable capacitor 511B, a significant change in capacitance may be achieved at high speed by switching the power supply state of the electromagnet 715 of the second variable capacitor 511B when switching the plasma, thereby shortening the switching time.

In addition, since the operating range of the bellows 630 may be reduced, the fracture life of the bellows 630 may be extended, and the periodic replacement cycle of the matching box 35 may be extended.

The bellows 730 may be designed considering its fracture life, which allows the overall lifetime of the matching box 35 to be extended.

The radio-frequency power supply line 551 is supplied with a high power for plasma generation. Thus, in the configuration that switches capacitors connected by switching, there is a risk of contact wear or noise occurring during ON/OFF operations. In contrast, in the second variable capacitor 511B and the fourth variable capacitor 512B, there is no contact wear due to switching, and no noise occurs during ON/OFF operations.

The first reactance element 511 has been described as including one first reactance element 511 and one second reactance element 512 connected in parallel, but is not limited thereto. The first reactance element 511 may include a plurality of second reactance elements 512 connected in parallel in addition to the one first reactance element 511. As a result, even in substrate processing involving a plurality of plasma states, the capacitance of the first reactance element 511 may be adjusted for each plasma state by switching the state of each second variable capacitor 511B.

The matching box 35 including the impedance matching circuitry 510 illustrated in FIG. 3 has been described as being applied to a batch-type substrate processing apparatus 100, but is not limited thereto. The matching box may also be applied to a matching box in a single-wafer type substrate processing apparatus.

According to the aspect, a plasma processing apparatus and a matching box may be provided that are capable of shortening a matching adjustment time.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a gas supply configured to supply a processing gas;
a radio-frequency power source;
a pair of plasma electrodes; and
a matching box disposed between the pair of plasma electrodes and the radio-frequency power source,
wherein the matching box includes:
a radio-frequency power supply line configured to receive radio-frequency power from the radio-frequency power source,
a ground line that is grounded,
a first load line connected to one of the pair of plasma electrodes,
a second load line connected to a remaining one of the pair of plasma electrodes,
impedance matching circuitry connected to the radio-frequency power supply line, the first load line, the second load line, and the ground line, and including a first reactance element,
a radio-frequency sensor provided in the radio-frequency power supply line and configured to detect the radio-frequency power, and
a matching box controller configured to receive a detection value from the radio-frequency sensor and control the first reactance element, and
wherein the first reactance element includes:
a first variable capacitor having a continuously variable capacitance, and
a second variable capacitor connected in parallel with the first variable capacitor and configured to switch between a first state having a first capacitance and a second state having a second capacitance.

2. The plasma processing apparatus of claim 1, wherein the first reactance element is disposed between the radio-frequency power supply line and the ground line.

3. The plasma processing apparatus of claim 2, wherein the impedance matching circuitry further includes a second reactance element disposed between the first load line and the second load line,
wherein the second reactance element includes:
a third variable capacitor having continuously variable capacitance, and
a fourth variable capacitor connected in parallel with the third variable capacitor and configured to switch between a third state having a third capacitance and a fourth state having a fourth capacitance, and
wherein the matching box controller is configured to receive the detection value from the radio-frequency sensor and control the first reactance element and the second reactance element.

4. The plasma processing apparatus of claim 3, further comprising:
a third reactance element disposed between the radio-frequency power supply line and the first load line; and
a fourth reactance element disposed between the second load line and the ground line,
wherein the third reactance element and the fourth reactance element are inductors.

5. The plasma processing apparatus of claim 3, further comprising:
a voltage sensor configured to detect a peak-to-peak value of a potential difference between the first load line and the second load line,
wherein the matching box controller is configured to receive the detection values from the radio-frequency sensor and the voltage sensor and control the first reactance element and the second reactance element.

6. The plasma processing apparatus according to claim 1, wherein the matching box controller is configured to:
set the second variable capacitor to the first state when a first plasma is generated by supplying a first processing gas from the gas supply; and
set the second variable capacitor to the second state when a second plasma is generated by supplying a second processing gas different from the first processing gas from the gas supply.

7. A matching device disposed between a pair of plasma electrodes and a radio-frequency power source, the matching device comprising:
a radio-frequency power supply line configured to receive radio-frequency power from the radio-frequency power source;
a ground line that is grounded;
a first load line connected to one of the pair of plasma electrodes;
a second load line connected to a remaining one of the pair of plasma electrodes;
impedance matching circuitry connected to the radio-frequency power supply line, the first load line, the second load line, and the ground line, and including a first reactance element;
a radio-frequency sensor provided in the radio-frequency power supply line and configured to detect the radio-frequency power; and
a matching device controller configured to receive a detection value from the radio-frequency sensor and control the first reactance element,
wherein the first reactance element includes:
a first variable capacitor having a continuously variable capacitance, and
a second variable capacitor connected in parallel with the first variable capacitor and configured to switch between a first state having a first capacitance and a second state having a second capacitance.
